(19) United States
(12) Patent Application Publication
(10) Pub. No.: US 2014/0056441 A1
(43) Pub. Date: Feb. 27, 2014

(54) POLICY-BASED VEHICLE HORN FUNCTIONS

(71) Applicants: Gaurav Chhaunker, Hyderabad (IN); John G. Musial, Newburgh, NY (US); Sandeep R. Patil, Pune (IN); Gandhi Sivakumar, Bentleigh (AU)

(72) Inventors: Gaurav Chhaunker, Hyderabad (IN); John G. Musial, Newburgh, NY (US); Sandeep R. Patil, Pune (IN); Gandhi Sivakumar, Bentleigh (AU)

(73) Assignee: INTERNATIONAL BUSINESS MACHINES CORPORATION, Armonk, NY (US)

(21) Appl. No.: 13/592,999

(22) Filed: Aug. 23, 2012

(51) Int. Cl. H03G 3/00

(52) U.S. Cl. 381/107

(57) ABSTRACT

Vehicle horn functions are implemented by a computer processor integral with a vehicle and logic executable by the computer processor. The logic derives a current value associated with a component defined by a policy, retrieves from a data file a volume setting mapped to the current value, and modifies operation of a horn in the vehicle to produce a volume corresponding to the volume setting when an operator of the vehicle activates the horn.

### BACKGROUND

The present invention relates to policy-based noise pollution control and, more specifically, to environmentally-cognizant vehicle horn functions.

Unrestricted use of vehicle horns on the road contributes to what is becoming an ever-increasing concern over noise pollution. While a vehicle's horn can be an important safety component of a vehicle (e.g., in terms of notifying vehicles or pedestrians of the vehicle's presence), it can also be a source of frustration and distraction for others. For example, there are many times of the day when the frequent use of a horn is inconvenient, such as during sleeping hours. Also, there are many locations in which the over-use of a vehicle horn at any time of the day can be problematic (e.g., near hospitals and nursing homes) or during specific times of the day (e.g., schools, libraries, courts, etc.)

### SUMMARY

According to one embodiment of the present invention, a system for implementing vehicle horn functions is provided. The system includes a computer processor integral with a vehicle and logic executable by the computer processor. The logic implements a method. The method includes deriving a current value associated with a component defined by a policy, and retrieving from a data file a volume setting mapped to the current value. The method also includes modifying operation of a horn in the vehicle to produce a volume corresponding to the volume setting when an operator of the vehicle activates the horn.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 depicts a block diagram of a system upon which policy-based vehicle horn functions may be implemented according to an embodiment of the present invention;

FIG. 2 depicts a flow diagram describing a process for implementing policy-based vehicle horn functions according to an embodiment of the present invention;

FIG. 3 depicts a flow diagram describing a process for implementing policy-based vehicle horn functions according to another embodiment of the present invention;

FIG. 4 depicts a flow diagram describing a process for implementing policy-based vehicle horn functions according to a further embodiment of the present invention;

FIG. 5 depicts a data file storing sample policies used in implementing the policy-based vehicle horn functions according to an embodiment of the present invention; and

FIG. 6 depicts a data file storing additional sample policies used in implementing the policy-based vehicle horn functions according to an embodiment of the present invention.

### DETAILED DESCRIPTION

According to an exemplary embodiment, policy-based vehicle horn functions (also referred to herein as “vehicle horn functions”) for managing noise pollution are provided. The policy-based vehicle horn functions modify the volume of a vehicle's horn based on various policies. The policies may be based on the time of day and/or may be based on the particular location of the vehicle. Volume settings for these policies may be established by one or more government agencies. For example, a low volume setting may be prescribed for a time of day in which most people are sleeping (e.g., 12:00:00 to 08:00:00). Additionally, or alternatively, a low volume setting may be prescribed according to geographic location (e.g., a radius surrounding a hospital) regardless of the time of day.

The policy-based vehicle horn functions may be configured at least in part by an owner or operator of the vehicle through a vehicle interface or may be installed by the vehicle manufacturer at the time of manufacture or by a dealership at or before a point of purchase based on policies set for a community or region in which the vehicle is or will be sold. Thus, the policies may vary depending on rules adopted by an agency or laws enacted for a geographic location in which the vehicle is sold. These and other features of the vehicle horn functions will now be described.

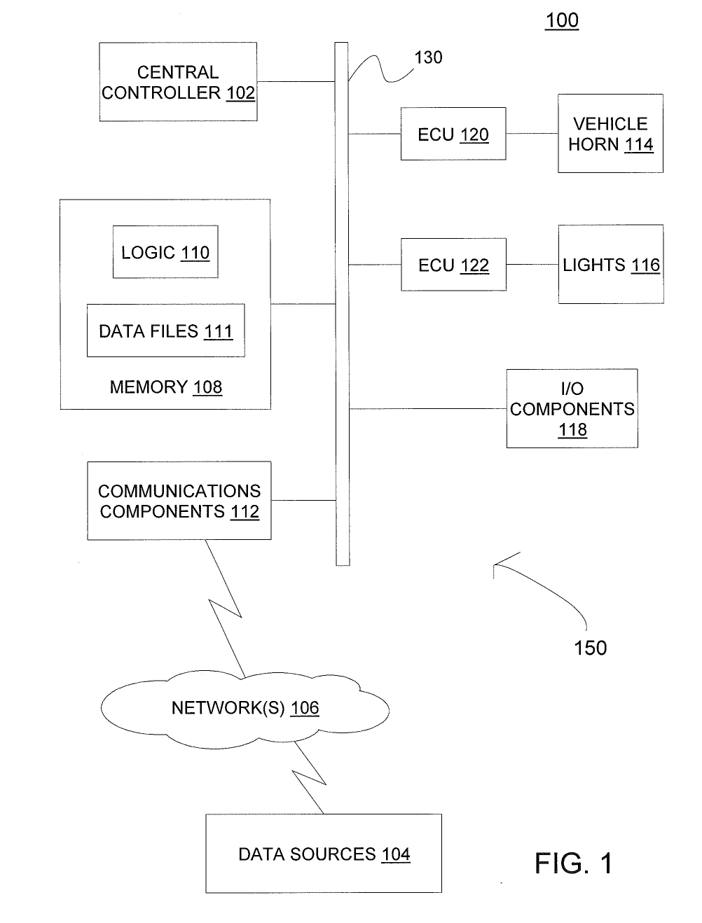

Turning now to FIG. 1, a system 100 upon which the vehicle horn functions may be implemented will now be described in an exemplary embodiment. The system 100 of FIG. 1 includes a vehicle 150 and data sources 104 communicatively coupled to one or more networks 106. The vehicle 150 may be a personal vehicle or a commercial vehicle and may be implemented as any type of automotive vehicle known in the art, e.g., car, truck, van, motorcycle, etc.

The vehicle 150 includes a central controller 102 and memory device 108 communicatively coupled to a bus 130. The central controller 102 may be implemented using one or more computer processors operating in response to computer programs stored in a storage medium accessible by the processors. One of these computer programs is logic 110, which implements the exemplary vehicle horn functions described herein. The memory device 108 is an internal storage system of the vehicle 150 and stores the logic 110.

The computer processors of the central controller 102 manage and control the transmission of data over the bus 130 that enables various vehicle components to function, as will be described further herein.

The communications components 112 may be implemented using a variety of devices or systems. For example, the communications components 112 may include navigation system with global positioning system (GPS) components for tracking a location of the vehicle 150. Alternatively, the communications components 112 may include a telematics system with GPS components that communicate with a telematics service provider to download policies adopted by a particular agency for a region traveled by the vehicle 150. The communications components 112 request and receive data over the networks 106 and provide this data to the central controller 102. The data may include policies received from the data sources 104 for use in implementing the vehicle horn functions. In an embodiment, government or other agencies establish volume settings for particular times of the day and/or particular geographic locations. The volume settings may be stored in the data files 111 in the memory device 108.

The data sources 104 may include database systems managed by government or other agencies, telematics service providers, and/or other sources of policy information. The data sources 104 provide policy information to the vehicle 150 over the networks 106 via network-enabled computer systems of these sources 104. The policy information may be stored in the data files 111 of the memory device 108.

In an embodiment, the owner or operator of the vehicle 150 may configure at least a portion of the volume settings, e.g., where no external policies exist. For example, the logic 110 may be configured with a user interface that is accessible through I/O components 118 of the vehicle 150. In one embodiment, the I/O components 118 include a navigation system display screen with input controls. Alternatively, the I/O components 118 may include an infotainment system including display screen and input controls. The I/O components 118 are communicatively coupled to the central controller via the bus 130. The user selected volume settings may be stored in the data files 111 in the memory device 108.

The central controller 102 communicates with a horn 114 of the vehicle 150 via a corresponding electronic control unit (ECU) 120. The ECU 120 includes a computer processor including circuitry or and/or software that directs the vehicle horn to operate in accordance with the volume settings corresponding to set policies. In an alternative embodiment, the volume settings of the horn 114 are modified electromechanically, e.g., via a muffler or a baffle that engages with the horn to increase or decrease the volume of the horn.

The central controller 102 also communicates with lights 116 of the vehicle 150 via a corresponding electronic control unit (ECU) 122. The ECU 122 includes a computer processor including circuitry or and/or software that directs the vehicle lights to operate in accordance with the volume settings corresponding to set policies. The lights 116 may include the front headlights and rear taillights. In an embodiment, when the volume settings have been modified such that the horn is operated at a lowest possible volume, the logic 110 is configured to activate the lights 116 via the central controller 102, bus 130, and ECU 122. In this manner, the intended warning of the vehicle horn is intensified by the activated lights operating in conjunction with the horn, such that the subject of the intended warning is better able to perceive the warning.

The bus 130 may be a wireline network bus (e.g., cabling) or may a wireless network of the vehicle 150. The networks 106 may include any type of known networks including, but not limited to, cellular, satellite, and terrestrial. The networks 106 may include a wide area network (WAN), a local area network (LAN), a global network (e.g. Internet), a virtual private network (VPN), and an intranet. The networks 106 may be implemented using any kind of physical network implementation known in the art.

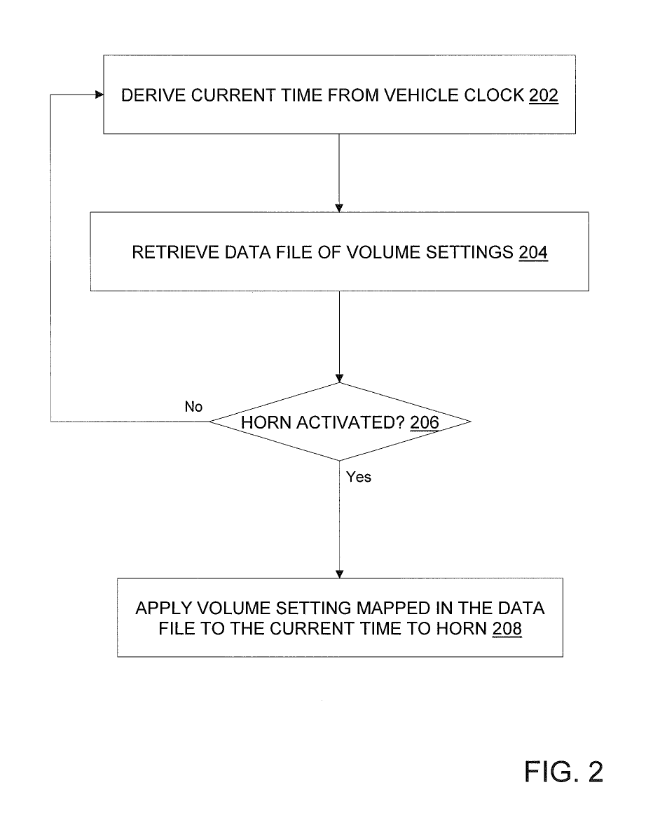

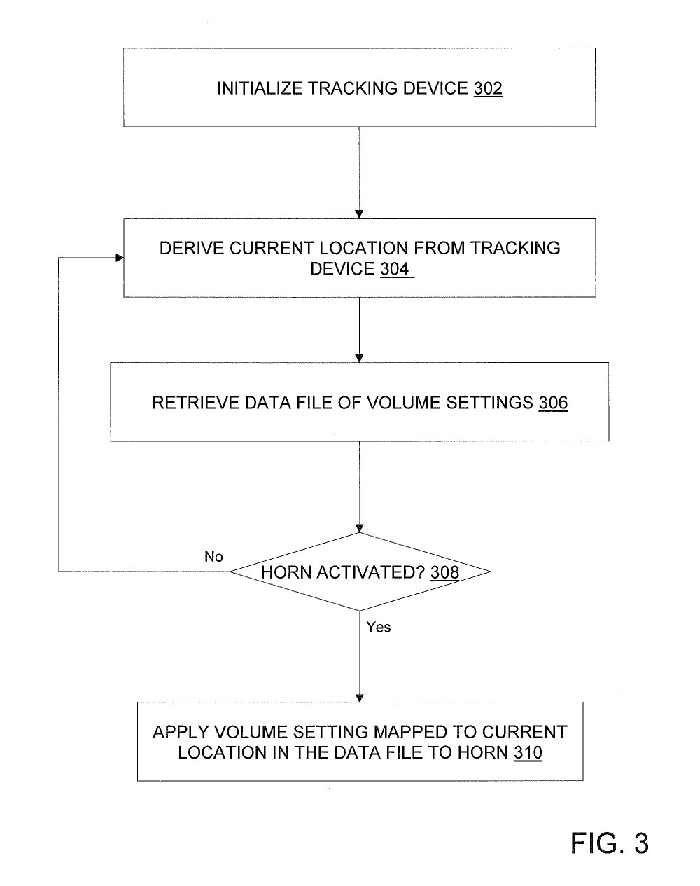

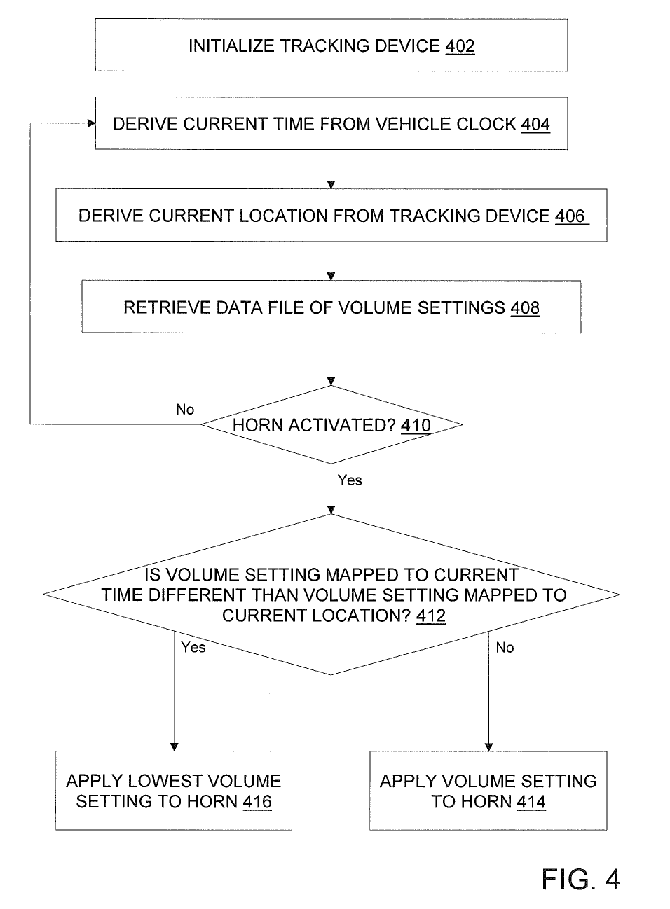

FIGS. 2-4 illustrate embodiments of the vehicle horn functions. The embodiments monitor values associated with a component of a policy, retrieve a volume setting mapped to the value in a data file, and modify operation of the vehicle horn 114 based on the volume setting. The process described in FIG. 2 is directed to time-based policies in which a current value monitored relates to a time component. The process described in FIG. 3 is directed to location-based policies in which a current value monitored relates to a location of the vehicle 150. The process described in FIG. 4 is directed to a combination of time-based policies and location-based policies. For each of FIGS. 2-4, the processes assume that a user has powered on the vehicle 150.

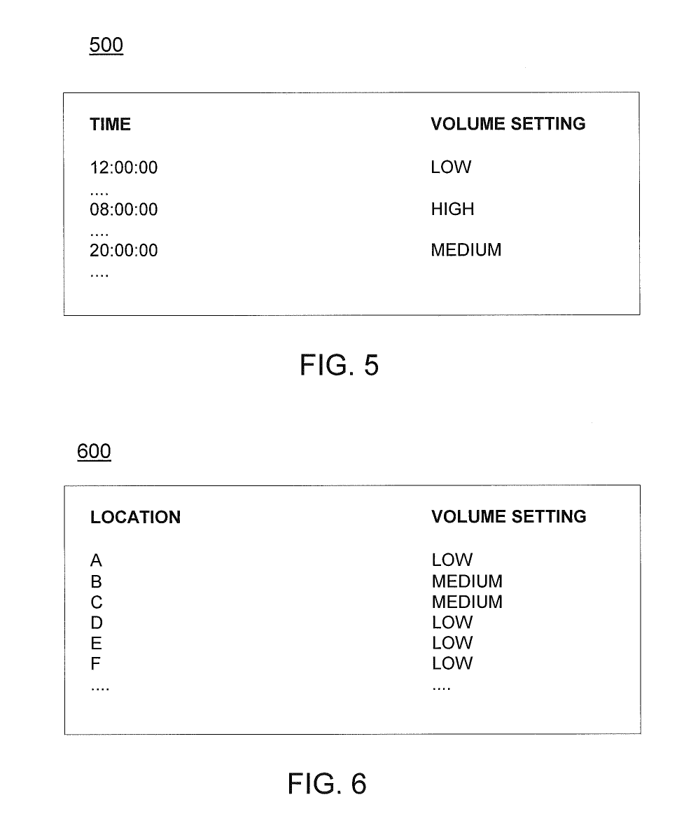

At step 202, the logic 110 receives the current time from a clock in the vehicle 150. The logic 110 retrieves a data file 111 of volume settings from the memory device 108 at step 204 and finds the volume setting mapped to a time in the data file 111 that corresponds to the current time. As shown in FIG. 5, for example, a data file 500 lists times of the day and assigned volume settings mapped to these times. For example, from 12:00:00 to 07:59:59 (a time range in which most of the population is sleeping), the volume setting assigned is “LOW,” which means a lowest prescribed volume. The data file 111 also indicates from 08:00:00 to 19:59:59 (a time in which most of the population is awake), the volume setting assigned is “HIGH,” which indicates a highest prescribed volume. Further, from 20:00:00 to 23:59:59, the volume setting assigned is “MEDIUM,” which indicates a volume substantially halfway between the lowest and highest volume.

At step 206, the logic 110 determines whether the operator of the vehicle 150 has activated the horn 114. If not, the process returns to step 202 and the current time (updated) is derived from the vehicle clock. If, however, the horn 114 has been activated at step 206, the logic 110 applies the volume setting to the horn 114 based on the time at step 208. As indicated above, if the horn 114 has been activated at the lowest volume setting, the lights 116 may also be activated to intensify the warning of the horn 114.

Turning now to FIG. 3, a process directed to location-based policies will now be described in an embodiment. At step 302, a tracking device (e.g., communications components 112) is initialized. At step 304, the logic 110 receives the current location from the communications components 112 in the vehicle 150. The current location may be GPS coordinates.

At step 306, the logic 110 retrieves a data file 111 of volume settings from the memory device 108, and finds the volume setting mapped to the location derived in step 304. As shown in FIG. 6, for example, a data file 600 lists locations and assigned volume settings mapped to these locations. For example, location A may be indicative of particular GPS coordinates and may also include a descriptive term (e.g., hospital) associated with the GPS coordinates. It will be understood that the alphabetical indications of locations are provided for simplicity and are not to be construed as limiting in scope. Another location, B, may refer to GPS coordinates for a location in which limited volume controls are desired (e.g., a library or school).

At step 308, the logic 110 determines whether the operator of the vehicle 150 has activated the horn 114. If not, the process returns to step 304 and the current location (updated) is derived from the tracking system. If, however, the horn 114 has been activated at step 308, the logic 110 applies the volume setting to the horn 114 based on the location at step 310. As indicated above, if the horn 114 has been activated at the lowest volume setting, the lights 116 may also be activated to intensify the warning of the horn 114.

It will be understood that various modifications to the time-based process described in FIG. 2 and the location-based process of FIG. 3 may be implemented in order to realize the advantages of the embodiment. For example, the time-based volume settings may be defined at a more granular level using elements of the location-based policies. Turning now to FIG. 4, a combination of time-based policies and location-based policies used in implementing the vehicle horn functions will now be described.

At step 402, a tracking device (e.g., communications components 112) is initialized. At step 404, the logic 110 receives the current time from the vehicle clock. At step 406, the logic 110 receives the current location from the communications components 112 in the vehicle 150.

At step 408, the logic 110 retrieves the data files 111 (e.g., files 500 and 600) of volume settings from the memory device 108, and finds the volume setting mapped to the current time and the volume setting mapped to the current location.

At step 410, the logic 110 determines whether the operator of the vehicle 150 has activated the horn 114. If not, the process returns to step 404 and the current time (updated) and location (updated) are derived from the tracking system. If, however, the horn 114 has been activated at step 410, the logic 110 determines if the volume setting mapped to the current time is different than the volume setting mapped to the current location at step 412. If so, the logic 110 applies the lowest volume of the two volume settings to the horn 114 at step 416. Otherwise, the logic 110 applies the volume setting (which is the same for both time and location) to the horn 114 at step 414. For example, suppose the current time is 08:00:00 (which is mapped to a volume setting of HIGH) and the current location is A (which is mapped to a volume setting of LOW). The logic 110 will apply the LOW setting to the horn 114. As indicated above, if the horn 114 has been activated at the lowest volume setting, the lights 116 may also be activated to intensify the warning of the horn 114.

In one embodiment, the logic 110 may be configured to apply weights to the time and location values in determining which volume setting to select. For example, in establishing policies for volume settings with regard to a location, the safety concerns of having full volume control of a vehicle's horn 114 may be weighed against the safety and/or inconvenience incurred at the location for which the volume controls are applied. For example, in a busy intersection (adjacent to a hospital) that is known to be fraught with accidents, a volume setting of MEDIUM rather than a setting of LOW may be preferable for this location even though it is adjacent to a hospital.

In another embodiment, the vehicle horn functions may be overridden based on certain conditions. The logic 110 may be configured to assess circumstances that may trigger this override function. For example, even when the vehicle 150 is determined to be in a location that dictates the use of a low volume setting, the vehicle horn 114 nonetheless may be activated at full volume when an extreme braking condition is detected (e.g., the brake has been depressed quickly or at a sharp angle with respect to the vehicle floor). The override function may be implemented in other emergency situations, such as when the operator is rushing a passenger to a hospital. In this example, the logic 110 may be configured with a manual override function that is implemented, e.g., via a control function on the vehicle or through a user interface (e.g., one of I/O components 118). The override function in the emergency situation may be operative for the duration of the trip (e.g., until the vehicle 150 is powered off or in park).

Technical effects of the invention enable policy-based vehicle horn functions (also referred to herein as “vehicle horn functions”) for managing noise pollution. The policy-based vehicle horn functions modify the volume of a vehicle's horn based on various policies. The policies may be based on the time of day and/or may be based on the particular location of the vehicle. The policy-based vehicle horn functions may be configured at least in part by an owner or operator of the vehicle through a vehicle interface or may be installed or configured by the vehicle manufacturer at the time of manufacture or by a dealership at or before a point of purchase based on policies set for a community or region in which the vehicle is or will be sold.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A system for implementing vehicle horn functions, comprising:
a computer processor integral with a vehicle; and
logic executable by the computer processor, the logic configured to implement a method, the method comprising:
deriving a current value associated with a component defined by a policy;
retrieving, from a data file, a volume setting mapped to the current value; and
modifying operation of a horn in the vehicle to produce a volume corresponding to the volume setting when an operator of the vehicle activates the horn.

2. The system of claim 1, wherein the component is time of day and the logic receives the current value from a clock in the vehicle over a vehicle network.

3. The system of claim 2, wherein the logic is further configured to implement:
deriving another current value associated with another component defined by another policy;
retrieving, from another data file, a volume setting mapped to the other current value; and
upon determining the volume setting mapped to the other current value is different than the volume setting mapped to the current value, selecting one of the volume setting mapped to the other current value and the volume setting mapped to the current value for modifying the operation of the horn.

4. The system of claim 3, wherein the other component is a geographic location and the logic receives the other current value from a global positioning system device in the vehicle over the vehicle network.

5. The system of claim 1, wherein the component is a geographic location and the logic receives the current value from a global positioning system device in the vehicle over a vehicle network.

6. The system of claim 1, wherein the computer processor downloads the policy over a network.

7. The system of claim 1, wherein the volume setting is a lowest defined volume of the horn, the logic further configured to implement:
activating external lights on the vehicle when the horn is activated.

8. The system of claim 1, wherein the operation of the horn is modified to a lower volume setting via a muffler device.
